(19) United States
(12) Patent Application Publication
(10) Pub. No.: US 2025/0263868 A1
(43) Pub. Date: Aug. 21, 2025

(54) GALLIUM NITRIDE SINGLE CRYSTAL SUBSTRATE AND METHOD FOR PRODUCING THE SAME

(71) Applicant: SUMITOMO CHEMICAL COMPANY, LIMITED, Tokyo (JP)

(72) Inventors: Tetsuji FUJIMOTO, Ibaraki (JP); Takashi SATO, Ibaraki (JP); Takayuki SUZUKI, Ibaraki (JP); Toshio KITAMURA, Ibaraki (JP); Masatomo SHIBATA, Ibaraki (JP)

(21) Appl. No.: 19/053,840

(22) Filed: Feb. 14, 2025

(30) Foreign Application Priority Data
Feb. 16, 2024 (JP) 2024-021692

(51) Int. Cl. C30B 29/40; C30B 25/02; C30B 31/06

(52) U.S. Cl. CPC C30B 29/406; C30B 25/02; C30B 31/06

(57) ABSTRACT

There is provided a gallium nitride single crystal substrate, which is a gallium nitride single crystal substrate having a diameter of 50 mm or more, with a low-index crystal plane closest to a main surface being (0001), and in which a Mn concentration in the substrate is 5×10¹⁷ cm⁻³ or more; and secondary ion mass spectrometry at a plurality of arbitrary points on the main surface reveals that a variation in the Mn concentration is within ±20% from an average value.

### TECHNICAL FIELD

The present disclosure relates to a gallium nitride single crystal substrate and a method for producing the same.

### DESCRIPTION OF RELATED ART

Group III nitride semiconductors, typified by gallium nitride (GaN), are widely used as materials for forming semiconductor devices, such as light-emitting devices and electronic devices. In order to improve the quality (semiconductor properties, etc.) of the semiconductor devices constituted by group III nitride semiconductors, it is desirable to produce semiconductor stacks or nitride semiconductor free-standing substrates used for semiconductor devices, with good crystal quality.

Further for example, patent document 1 discloses a method for producing a gallium nitride single crystal substrate by a VAS (Void-Assisted Separation) method, as a method for producing a GaN single crystal substrate. Also, patent document 2 discloses a method including the steps of epitaxially growing a semiconductor layer composed of GaN on a substrate, slicing the GaN layer, thereby fabricating a GaN free-standing substrate.

Further, there is a demand for a semi-insulating GaN single crystal substrate having high resistance, for applications such as a production of a high frequency semiconductor device. Dopants used to obtain the semi-insulating GaN single crystal substrate include iron (Fe), manganese (Mn), and carbon (C), and among these, use of manganese (Mn) enables the production of a highly resistive substrate. For example, Patent document 3 discloses a method for producing a nitride crystal substrate, in which a crystal layer composed of a single crystal of a group III nitride semiconductor containing manganese is epitaxially grown above a base substrate by hydride vapor phase epitaxy (HVPE).

[Patent document 1] JP 2003-178984 A

[Patent document 2] JP 2008-156189 A

[Patent document 3] JP 2021-109813 A

However, it has become clear that in the case of a Mn-doped GaN substrate, especially a large-diameter GaN substrate (e.g., having a diameter of 50 mm or more), there is a problem that a large variation occurs in a Mn concentration distribution in the plane of the substrate.

### SUMMARY OF THE INVENTION

An object of the present invention is to provide a highly resistive gallium nitride single crystal substrate that is uniformly doped with Mn.

According to one aspect of the present disclosure, there is provided a gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more; and

secondary ion mass spectrometry at a plurality of arbitrary points on the main surface reveals that a variation in the Mn concentration is within ±20% from an average value.

According to another aspect of the present disclosure, there is provided a gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more, and

measurement at a plurality of arbitrary points on the main surface reveals that a variation in resistivity is within ±20% from an average value.

According to further another aspect of the present disclosure, there is provided a gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more, and

measurement at a plurality of arbitrary points on the main surface reveals that a variation in a Vickers hardness is within ±2% from an average value.

According to further another aspect of the present disclosure, there is provided a gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more, and

measurement of a surface roughness at a plurality of arbitrary points on the main surface reveals that a variation in arithmetic mean height Sa is within ±20% from an average value.

According to further another aspect of the present disclosure, there is provided a gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more, and

measurement at a plurality of arbitrary points on the main surface reveals that a variation in a minimum light transmittance in a wavelength range of 700 nm or more and 900 nm or less is within ±20% from an average value.

According to further another aspect of the present disclosure, there is provided a method for producing a gallium nitride single crystal substrate, the method including the steps of:

(a) preparing a base substrate composed of a gallium nitride single crystal having (0001) that is a low-index crystal plane closest to a main surface;

(b) epitaxially growing a gallium nitride single crystal having a Mn concentration of 5×10¹⁷ cm⁻³ or more on the main surface of the base substrate; and

(c) obtaining a gallium nitride single crystal substrate having a diameter of 50 mm or more from the gallium nitride single crystal epitaxially grown in the step (b),

wherein in the step (b), a gas containing HCl is intermittently introduced to periodically etch a growth interface, thereby uniformly doping crystal with Mn.

According to the present disclosure, a high-resistive gallium nitride single crystal substrate that is uniformly doped with Mn can be provided.

### BRIEF DESCRIPTION OF THE DRAWING

FIG. 1 is a flowchart illustrating a method for producing a gallium nitride single crystal substrate according to one embodiment of the present invention.

FIG. 2A is a schematic cross-sectional view illustrating a part of a method for producing a gallium nitride single crystal substrate according to one embodiment of the present invention.

FIG. 2B is a schematic cross-sectional view illustrating a part of a method for producing a gallium nitride single crystal substrate according to one embodiment of the present invention.

FIG. 2C is a schematic cross-sectional view illustrating a part of a method for producing a gallium nitride single crystal substrate according to one embodiment of the present invention.

FIG. 3A is a photograph of a region on the main surface of a gallium nitride single crystal substrate that is uniformly doped with Mn.

FIG. 3B is a photograph of a region on the main surface of a gallium nitride single crystal substrate that is non-uniformly doped with Mn.

FIG. 4A is a photograph of a substrate of example 1 according to one example of the present invention.

FIG. 4B is a photograph of a substrate of comparative example 1 according to one example of the present invention.

### DETAILED DESCRIPTION OF THE INVENTION

<Findings Obtained by the Inventors>

First, the findings obtained by the inventors will be described.

While repeatedly experimenting with a growth of Mn-doped GaN crystals, the inventors found a phenomenon in which when GaN crystal is doped with Mn at, for example, 5×10¹⁷ cm⁻³ or more so as to increase the resistance of the crystal, there is a variation in the performance of the device fabricated on the substrate.

Then, it has become clear that the factor that causes the above-described variation in device performance is correlated with the concentration of Mn incorporated in the crystal.

Mn has a property that an amount of Mn incorporated into a crystal is likely to change depending on the inclination of a crystal plane orientation on the surface during crystal growth. Therefore, when a morphology of a slightly inclined plane that is slightly inclined from a c-plane appears on the surface during crystal growth, the amount of Mn incorporated in that region changes, and unevenness in the Mn concentration is likely to occur in the crystal plane. This morphology occurs due to the influence of an internal residual stress during crystal growth and crystal c-plane warping. Particularly, in the case of GaN crystal growth, c-plane warping is likely to occur in the crystal during growth. Therefore it is found that, particularly, when producing a large-diameter GaN substrate having a diameter exceeding 50 mm, under influence of such a crystal c-plane warping, the growth plane is inclined from (0001), which is an original growth plane orientation, and morphology of depending on the inclination of the growth plane orientation at that location appears in the crystal growth plane, and therefore the regions with different Mn concentrations is more likely to occur.

The inventors have conducted extensive research into the above-described described problem. The reason why there is a variation in the way Mn is incorporated into the GaN crystal is that a slight inclined surface that is slightly inclined from the c-plane appears on the growth plane during crystal growth. The reason why a slightly inclined surface is formed at the growth interface is considered to be that variations occur in the density and orientation of atomic steps formed due to defects such as dislocations and deviation of the crystal plane from the c-plane. Therefore, the following technique is established: in the step of growing the Mn-doped GaN layer, by intermittently introducing a gas containing HCl to the growth interface and periodically etching the surface of the growing crystal, the flatness and cleanliness of the interface are maintained, thereby suppressing the formation of minute facets at the growth interface and preventing the above-described morphology from appearing on the growth surface, and thus, the GaN crystal is uniformly doped with Mn.

### One Embodiment of the Present Invention

Hereinafter, one embodiment of the present invention will be described with reference to the drawings.

Hereinafter, in a GaN crystal having a wurtzite structure, <0001> axis is referred to as “c-axis” and (0001) is referred to as “c-plane”. (0001) is sometimes referred to as “+c plane (gallium polar plane)” and (000-1) is sometimes referred to as “−c plane (nitrogen polar plane).” Further, <1-100> axis is referred to as “m-axis” and {1-100} is referred to as “m-plane.” The m-axis may also be written as <10-10> axis. Further, <11-20> axis is referred to as “a-axis” and {11-20} is referred to as “a-plane”.

### (1) Method for Producing a Gallium Nitride Single Crystal Substrate

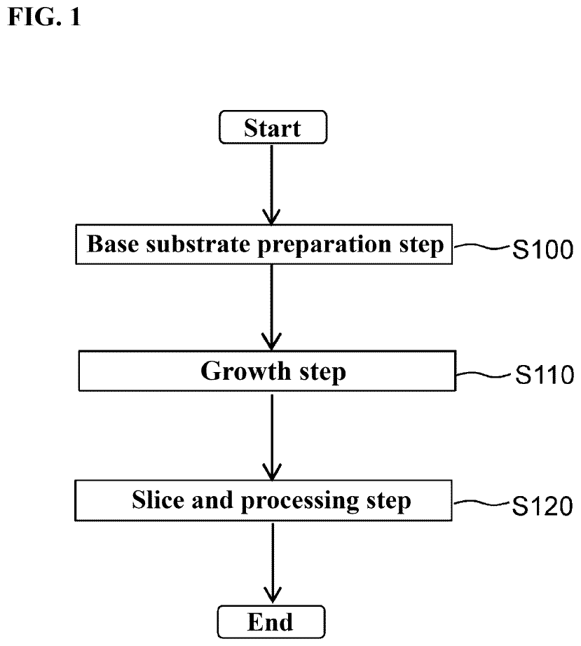

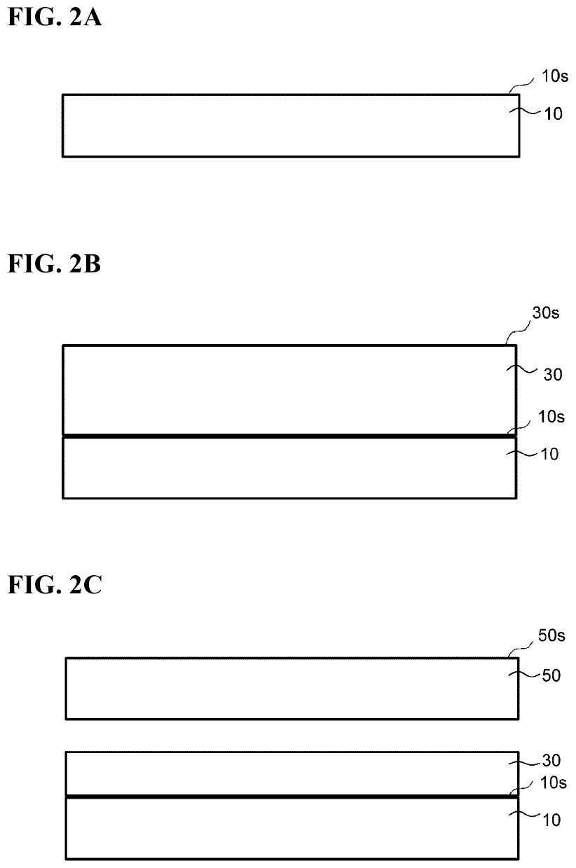

First, the method for producing a gallium nitride single crystal substrate according to this embodiment will be described. FIG. 1 is a flowchart illustrating a method for producing a gallium nitride single crystal substrate according to this embodiment. FIGS. 2A to 2C are schematic cross-sectional views illustrating a part of the method for producing a gallium nitride single crystal substrate according to this embodiment.

As illustrated in FIG. 1, the method for producing a gallium nitride single crystal substrate according to this embodiment includes, for example, a base substrate preparation step S100, a growth step S110, and a slicing and machining step S120.

### (S100: Base Substrate Preparation Step)

As illustrated in FIG. 2A, in the base substrate preparation step S100, a base substrate 10 is prepared, which is composed of gallium nitride single crystal and in which a low-index crystal plane closest to a main surface 10s is (0001) (c-plane). Specifically, a commercially available gallium nitride single crystal substrate (not a template, but a free-standing substrate) may be used as the base substrate 10, or the base substrate 10 composed of gallium nitride single crystal may be fabricated by the VAS (Void-Assisted Separation) method described in Patent document 1. The base substrate 10 may be Mn-doped or undoped, but is preferably Mn-doped. Thereby, the difference in a lattice constant caused by the difference in Mn concentration between the base substrate 10 and a growth layer 30 described later, can be reduced.

### (S110: Growth Step)

In the growth step S110, on the main surface 10s of the base substrate 10 prepared in the base substrate preparation step S100, a single crystal of GaN is epitaxially grown, as illustrated in FIG. 2B. Specifically, for example, by supplying GaCl gas and NH₃ gas to the heated base substrate 10 by the HVPE method, epitaxial growth is caused directly on the main surface 10s of the base substrate 10 to grow a growth layer 30.

In the growth step S110, for example, the growth layer 30 is grown under a predetermined growth condition. As a growth condition in this embodiment, the growth temperature is preferably set to, for example, 980° C. or more and 1200° C. or less. Further, in the growth step S110, a supply partial pressure ratio of NH₃ gas as a nitriding gas to GaCl gas as a group III source gas (hereinafter also referred to as “V/III ratio”) is preferably set to, for example, 0.1 or more and 5.0 or less.

In the growth step S110, by supplying GaCl gas, NH gas, and a Mn dopant gas, for example, manganese chloride (MnCl) gas, to the base substrate 10, a Mn-doped GaN layer having a Mn concentration of 5×10¹⁷ cm⁻³ to 1×10²⁰ cm⁻³ is epitaxially grown. MnCl₂ gas can be obtained, for example, by causing a reaction between solid Mn and HCl gas. The carrier gas may be either H₂ gas or N₂ gas, or both. In either case, it is preferable to control the flow rate so that the partial pressure of the MnCl₂ gas is 0.1 to 2.2 Pa using a mass flow controller.

Other growth conditions in the growth step S110 are, for example, as follows.

Growth pressure: 90 to 105 kPa, preferably 90 to 95 kPa
Partial pressure of GaCl gas: 1.5 to 15 kPa
Partial pressure of MnCl₂ gas: 0.1 to 2.2 Pa
N₂ gas flow rate/H₂ gas flow rate: 0 to 1

In the growth step S110, a gas containing HCl is intermittently introduced to periodically etch the growth interface (hereinafter, also referred to as intermittent etching), thereby uniformly doping the crystal with Mn. Specifically, for example, during growth with the c-plane as a growth plane, the supply of GaN source gas and dopant gas is temporarily stopped, and HCl gas and a carrier gas (for example, H₂ gas) are introduced. This suppresses the formation of minute facets on the growth plane, allowing uniform Mn doping. The introduction of the gas containing HCl is preferably performed at intervals of, for example, 5 to 10 minutes, for 0.5 to 1 minute each time.

In the growth step S110, it is preferable that the thickness of the growth layer 30 is, for example, 1 mm or more and 20 mm or less. When the GaN substrate, which is fabricated using the above-described VAS method, is used as the base substrate 10, the c-plane of the base substrate 10 often has a concave warping toward the surface (crystal growth plane). Even in the GaN substrate fabricated by other method, the c-plane may be curved due to a stress generated in the crystal during growth. The c-plane warping that occurs in the base substrate 10 is inherited by the growth layer 30 grown thereon, and due to the growth of the growth layer 30 to a certain thickness or more, stress is generated in the crystal to straighten the warping and flatten the c-plane, and the size of the c-plane warping becomes gradually small. Therefore, the growth layer 30 has a c-plane warping in accordance with its thickness. If the thickness of the growth layer 30 is less than 1 mm, there is a possibility that a sufficient stress for straightening the c-plane warping cannot be obtained. Further, in the subsequent slicing and machining step S120, it is difficult to obtain a GaN single crystal substrate with a sufficient thickness. In contrast, by setting the thickness of the growth layer 30 to 1 mm or more, the c-plane warping can be small. Further, in the subsequent slicing and machining step S120, a GaN single crystal substrate with a sufficient thickness can be obtained. On the other hand, if the thickness of the growth layer 30 exceeds 20 mm, the force attempting to straighten the c-plane warping may cause excessive strain to accumulate in the crystal, leading to the proliferation of dislocations in the crystal or the generation of microcracks. Further, if the internal residual stress in the GaN crystal becomes large, crystal fracture is more likely to occur in the slicing and machining step S120. In contrast, by setting the thickness of the growth layer 30 to 20 mm or less, the internal residual stress of the GaN crystal can be reduced, and cracks and fractures can be suppressed.

### (S120: Slicing and Machining Step)

In the slicing and machining step S120, as illustrated in FIG. 2C, for example, the growth layer 30 is sliced along a cutting plane approximately parallel to the main surface 30s of the growth layer 30 using a wire saw, etc. Thereby, at least one gallium nitride single crystal substrate 50 (also referred to as a substrate 50) having a diameter of 50 mm or more is obtained as an as-sliced substrate. At this time, it is preferable to slice the substrate 50 so that the thickness thereof is, for example, 300 μm or more and 1200 μm or less.

When the GaN substrate fabricated by the VAS method is used as the base substrate 10, the c-plane of the base substrate 10 normally has a warping with a radius of curvature of about 5 m in a direction that makes the surface concave. The radius of curvature of the c-plane of the substrate 50 cut out from the growth layer 30 is likely to be larger than the radius of curvature of the c-plane of the base substrate 10. Further, since the growth layer 30 is released from the stress applied by the base substrate 10 by being cut out from the base substrate 10, the radius of curvature of the c-plane is likely to become even larger than that of the state in which the growth layer 30 is formed on the base substrate 10 illustrated in FIG. 2B. Specifically, the radius of curvature of the c-plane of the substrate 50 is, for example, preferably 10 m or more, and more preferably 20 m or more. Thereby, the variation in the off-angle θ of the c-axis with respect to the normal on the main surface 50s of the substrate 50 (the maximum and minimum difference in the off-angle θ in the plane of the substrate) can be smaller than the variation in the off-angle of the c-axis of the base substrate 10.

Once the substrate 50 is obtained as an as-sliced substrate, both surfaces of the substrate 50 may be polished, for example, by a polishing device.

In this embodiment, the substrate 50 obtained in the slicing and processing step S120 may be used as a new base substrate 10, and the growth step S110 and the slicing and processing step S120 may be repeated a plurality of times (for example, four times or more). This type of growth is referred to as a generational growth in this specification. By performing such a generational growth rather than performing the growth all at once, the c-plane warping is alleviated each time the substrate 50 is cut out, and therefore the internal residual stress in the GaN crystal can be reduced. By reducing the internal residual stress, the occurrence of morphology is suppressed, making it easy to allow uniform Mn doping. There is no particular upper limit in the number of times that the generational growth is performed, but from the viewpoint of efficiently producing a large-diameter GaN single crystal substrate, it is preferable to perform 10 times or less, for example.

Through the above steps, the substrate 50 according to this embodiment is produced.

### (Fabrication Step of a Semiconductor Stack and a Fabrication Step of a Semiconductor Device)

After the substrate 50 is produced, for example, a semiconductor functional layer composed of a group III nitride semiconductor may be epitaxially grown on the substrate 50 to fabricate a semiconductor stack. After the semiconductor stack is fabricated, electrodes, etc., are formed on the semiconductor stack, and the semiconductor stack is diced to cut out chips of a predetermined size. In this way, a semiconductor device may be fabricated. The substrate 50 is uniformly doped with Mn, making it suitable for fabricating high a frequency semiconductor device, etc.

### (2) Gallium Nitride Single Crystal Substrate (Free-standing Nitride Semiconductor Substrate, Nitride Crystal Substrate)

Next, the gallium nitride single crystal substrate 50 according to this embodiment will be described.

In this embodiment, the substrate 50 obtained by the above-described producing method is a free-standing substrate composed of a single crystal GaN.

The diameter of the substrate 50 is, for example, 50 mm or more, and the thickness of the substrate 50 is, for example, 300 μm or more and 1 mm or less.

The Mn concentration in the substrate 50 is, for example, 5×10¹⁷ cm⁻³ or more and 1×10²⁰ cm⁻³ or less, preferably 5×10¹⁷ cm⁻³ or more and 5×10¹⁹ cm⁻³ or less, and more preferably 1×10¹⁸ cm⁻³ or more and 5×10¹⁹ cm⁻³ or less. The lower the Mn concentration in the substrate 50 is within a range where the resistance increases, the greater the effect that the variation in the Mn concentration in the substrate 50 has on a substrate resistance value. Therefore, the lower the Mn doping of the substrate, the more effective it is to perform intermittent etching more frequently during Mn doping growth. The Mn concentration is likely to be varied in the plane of the substrate. However, according to this embodiment, the substrate 50 is uniformly doped with Mn by intermittent etching, and therefore secondary ion mass spectrometry (SIMS) at a plurality of arbitrary points on the main surface 50s reveals that the Mn concentration is within a range of, for example, 5×10¹⁷ cm⁻³ to 1×10²⁰ cm⁻³, within ±20% from an average value.

The substrate 50 has, for example, a main surface 50s which serves as an epitaxial growth plane. In this embodiment, the low-index crystal plane closest to the main surface 50s is, for example, (0001).

The main surface 50s of the substrate 50 is, for example, mirror-finished by polishing, and the root-mean-square roughness RMS of the main surface 50s of the substrate 50 is, for example, less than 1 nm.

Further, in this embodiment, the impurity concentration in the substrate 50 obtained by the above-described producing method is lower than that in a substrate obtained by liquid phase growth such as the flux method or ammonothermal method.

Specifically, the hydrogen (H) concentration in the substrate 50 is, for example, less than 1×10¹⁷ cm⁻³, and preferably 5×10¹⁶ cm⁻³ or less. Further, the oxygen concentration in the substrate 50 is, for example, 5×10¹⁶ cm⁻³ or less, and preferably 3×10¹⁶ cm⁻³ or less.

The total content of silicon (Si) and oxygen (O) in the substrate 50 is preferably, for example, 1×1017 cm-3 or less. Further, the total content of Fe and carbon (C) in the substrate 50 is preferably, for example, 1×10¹⁷ cm 3 or less. Further, the total content of Si, O, Fe, and C in the substrate 50 is more preferably, for example, 1×10¹⁷ cm⁻³ or less.

The substrate 50 is doped with Mn, and the content of Si and O as n-type impurities is low compared to the Mn concentration, and therefore the substrate 50 becomes a high resistive substrate. The average resistivity of the substrate 50 is preferably, for example, 1×10⁸ Ωcm or more.

### (Curving of the C-plane and Variation in the Off-angle)

The radius of curvature of the c-plane of the substrate 50 is larger than, for example, the radius of curvature of the c-plane of the base substrate 10. Specifically, the radius of curvature of the c-plane of the substrate 50 is, for example, preferably 10 m or more, and more preferably 20 m or more. By the above-described intermittent etching, the impurity distribution in the crystal of the substrate 50 can be kept small, and the internal residual stress of the crystal can be reduced. As a result, cracks and fractures are less likely to occur even when the film is grown thicker than when intermittent etching is not performed, and the radius of curvature of the c-plane can be further large.

In this embodiment, the upper limit of the radius of curvature of the c-plane of the substrate 50 is not particularly limited, and is preferably as large as possible. When the c-plane of the substrate 50 is substantially flat, the radius of curvature of the c-plane may be considered to be infinite.

Further, in this embodiment, the large radius of curvature of the c-plane of the substrate 50 allows the variation in the off-angle 0 of the c-axis relative to the normal on main surface 50s of the substrate 50 to be smaller than the variation in the off-angle of the c-axis of base substrate 10.

Specifically, when an X-ray rocking curve measurement was performed for (0002) of the substrate 50 and the off-angle θ of the c-axis with respect to the normal on the main surface 50s was measured based on a diffraction peak angle of the (0002), the variation calculated from the maximum and minimum difference in the size of the off-angle θ within a diameter of 25 mm from the center of the main surface 50s is, for example, 0.14° or less, preferably 0.07° or less, and further preferably 0.05° or less.

In this embodiment, the lower limit of the variation in the off-angle 0 of the c-axis of the substrate 50 is not particularly limited, and the smaller the better. When the c-plane of the substrate 50 is substantially flat, the variation in the off-angle θ of the c-axis of the substrate 50 may be considered to be 0°.

Further, in this embodiment, since the curvature of the c-plane is isotropically small with respect to the main surface 50s of the substrate 50, the radius of curvature of the c-plane has little directional dependency.

Specifically, the difference between the radius of curvature of the c-plane in the direction along the a-axis, as determined by the above-described measurement method, and the radius of curvature of the c-plane in the direction along the m-axis, is, for example, 50% or less, and preferably 20% or less, of the larger of these radii of curvature.

### (Dislocation Density)

In this embodiment, the dislocation density on the surface of substrate 50 is lower than the dislocation density on the main surface 10s of base substrate 10.

In this embodiment, since the crystal growth proceeds so as to maintain the flatness of the crystal growth interface, a mechanism of locally concentrating the propagating dislocations does not work. Accordingly, there are no regions having particularly high dislocation density caused by concentration of dislocations, and the distribution of dislocation density is uniform in the plane of the substrate. It is confirmed by observing etch pits corresponding to dislocations formed by etching in a molten alkali, that the dislocation density in the GaN crystal does not increase even when the GaN crystal is doped with Mn at a high concentration.

### (In-plane Uniformity)

In the substrate 50 of this embodiment, the above-described intermittent etching makes the Mn concentration and various properties described below uniform in the plane.

Specifically, for example, secondary ion mass spectrometry (SIMS) at a plurality of arbitrary points on the main surface 50s reveals that the variation in Mn concentration is within ±20% from an average value. When selecting the plurality of arbitrary points on the main surface 50s, for example, three or more points are preferably selected, five or more points are more preferably selected, and ten or more points are even more preferably selected. Further, since the vicinity of the outer periphery of the substrate 50 is easily affected by polishing, etc., it is preferable to select a plurality of arbitrary points excluding, for example, a region extending from the outer periphery of the main surface 50s to a position 5 mm inward.

Further, for example, it is preferable that the variation in resistivity measured at a plurality of arbitrary points on the main surface 50s, is within ±20% from an average value. In-plane uniformity of the resistivity value indicates uniform Mn doping in the plane. The method for selecting a plurality of arbitrary points on the main surface 50s is as described above.

Further, for example, it is preferable that the variation in a Vickers hardness measured at a plurality of arbitrary points on the main surface 50s is within ±2% from an average value. Uniform Vickers hardness value in the plane indicates that Mn doping is uniform in the plane. The method for selecting a plurality of arbitrary points on the main surface 50s is as described above.

Further, for example, it is preferable that the variation in the arithmetic mean height Sa when the surface roughness is measured at a plurality of arbitrary points on the main surface 50s, is within ±20% from an average value. When there is a difference in the Mn concentration in a crystal, variation occurs in the mechanical strength and chemical reactivity of the crystal, and accordingly variation also occurs in the amount of removal during a polishing process in accordance with the variation in the Mn concentration, and this affects the variation in the Sa value. In-plan uniformity of the value of the arithmetic mean height Sa indicates uniform Mn doping in the plane. The method for selecting a plurality of arbitrary points on the main surface 50s is as described above.

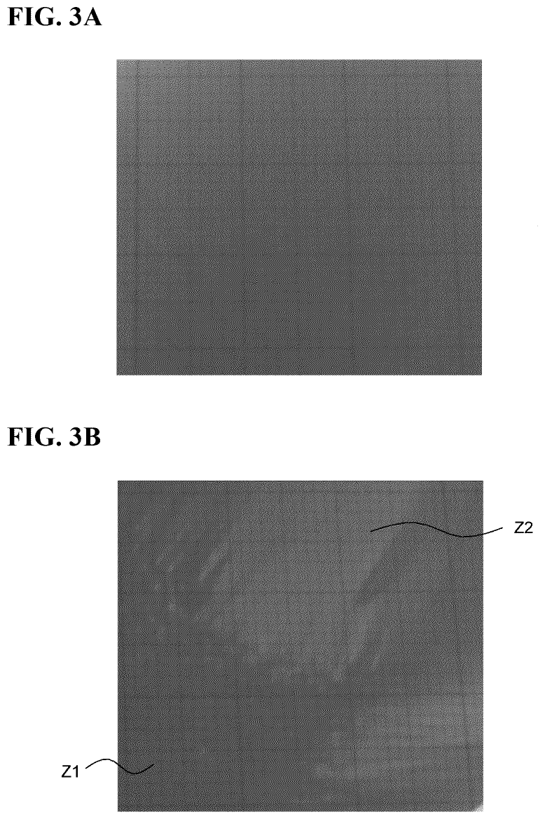

Further, in the region where the Mn concentration is non-uniform on the main surface 50s, color unevenness in accordance with the shading of the Mn concentration is observed. FIG. 3A is a photograph of a region that is uniformly doped with Mn, and FIG. 3B is a photograph of a region that is non-uniformly doped with Mn. As illustrated in FIG. 3A, in the region that is uniformly doped with Mn, no color unevenness is observed. On the other hand, as illustrated in FIG. 3B, in the region that is non-uniformly doped with Mn, color unevenness is observed. Specifically, a region Z1 where the Mn concentration is locally high has a dark color, and a region Z2 where the Mn concentration is locally low has a light color. The substrate 50 of this embodiment is uniformly doped with Mn in the plane, and therefore an entire in-plane region of the main surface 50s is a region without color unevenness as illustrated in FIG. 3A.

Further, the above-described color unevenness can also be checked by measuring the light transmittance of the substrate 50. For example, it is preferable that the variation in the minimum value of the light transmittance in a wavelength range of 700 nm or more and 900 nm or less at a plurality of arbitrary points on the main surface 50s, is within ±20% from an average value. The uniform light transmittance value in the plane indicates that there is no color unevenness and that Mn doping is uniform in the plane. The method for selecting a plurality of arbitrary points on the main surface 50s is as described above.

In addition, the light reflectance and light absorption coefficient of the substrate 50 may be measured to evaluate the color unevenness. For example, it is preferable that the variation in the maximum value of the light reflectance in the wavelength range of 600 nm or more and 700 nm or less at a plurality of arbitrary points on the main surface 50s, is within ±20% from an average value. Further, for example, it is preferable that the variation in the minimum value of the light absorption coefficient in the wavelength range of 600 nm or more and 700 nm or less at a plurality of arbitrary points on the main surface 50s, is within ±20% from an average value. The uniform light reflectance and light absorption coefficient in the plane indicates that there is no color unevenness and that Mn doping is uniform in the plane. The method for selecting a plurality of arbitrary points on the main surface 50s is as described above.

### Other Embodiments

The embodiment of the present invention has been specifically described above. However, the present invention is not limited to the above embodiment, and various modifications can be made without departing from the spirit and scope of the present invention.

The above-described embodiment shows a case where in the growth step S110, the growth layer 30 is epitaxially grown using the c-plane as a growth plane, but for example, in the middle of the growth step S110, a growth step using an inclined interface other than the c-plane as a growth plane, may be interposed. This allows dislocations to bend, propagate, meet, and annihilate more easily. However, during growth on the inclined interface as a growth plane, Mn is likely to become non-uniform, and therefore it is preferable that during the growth on the inclined interface, Mn doping is not performed, and the growth interface is returned to a flat surface with the c-plane as a growth plane, and then Mn doped growth is carried out while performing intermittent etching, and the substrate 50 is obtained from a crystalline region where the intermittent etching has been performed.

The above embodiment shows a case where the growth layer 30 is sliced using a wire saw in the slicing and machining step S120, but for example, an outer circumferential blade slicer, an inner circumferential blade slicer, etc., may also be used.

### EXAMPLE

Next, examples of the present invention will be described. These examples are merely examples of the present invention, and the present invention is not limited to these examples.

### (1) Fabrication of a Gallium Nitride Single Crystal Substrate

Gallium nitride single crystal substrates of example 1 and comparative example 1 were fabricated as follows.

### [Fabrication Conditions for the Gallium Nitride Single Crystal Substrate in Example 1]

### (Base Substrate)

### Material: GaN

Fabrication method: VAS method
Diameter: 2 inches

### Thickness: 400 μm

Low-index crystal plane closest to the main surface: c-plane
No pattern machining for the mask layer, etc., on the main surface.
Root mean square roughness RMS of the main surface: 2 nm
Off-angle on the main surface: 0.4° in the m direction (growth layer)

### Material: GaN

Growth method: HVPE method
Growth temperature: 980° C. to 1,020° C.
V/III ratio: 2 or more and 20 or less
Mn doping method: MnCl₂ gas
Partial pressure of MnCl₂ gas: 0.65 Pa
Thickness of the growth layer: 4500 μm (intermittent etching condition)

### Etching gas: HCl gas

Etching interval: 10 min/cycle
Etching time: 0.5 min/cycle (slicing and processing condition)
Thickness of the gallium nitride single crystal substrate: 400 μm
Kerf loss: 200 μm

### [Fabrication Conditions for the Gallium Nitride Single Crystal Substrate in Comparative Example 1]

(Base substrate) same as in example 1.
(Growth layer) same as in example 1.
(Intermittent etching) in comparative example 1, intermittent etching was not performed.
(Slicing and processing condition) same as in example 1.

### (2) Evaluation of In-plane Uniformity

On the main surface of the gallium nitride single crystal substrate of example 1 and comparative example 1, three arbitrary points (a, b, c) were selected, excluding the region from outer periphery of the main surface to a position 5 mm inward, and SIMS measurement, resistivity measurement, Vickers hardness measurement, surface roughness measurement, and light transmittance measurement at each point were performed. The measurement conditions for each measurement are as follows.

### (SIMS Measurement)

SIMS measurement was performed within a range of 10 μm deep from the main surface side of the substrate.

### (Resistivity Measurement)

Equipment: Hi-Resta-UX (MCP-HT800) manufactured by Nitto Seiko Analytech Co., Ltd.
Method: Front and back contact measurement (with guide ring)
Probe type: URS
Probe size: φ5.9 mm (guide ring inner diameter φ11 mm)
Applied voltage: 500V
Measurement method: Average value of 10 measurements

### (Vickers Hardness Measurement)

Equipment: HMV-G31-FA-D manufactured by Shimadzu Co., Ltd.
Measurement method: Average value of 5 measurements
(Surface roughness measurement)
Equipment: VertScan, manufactured by Ryoka Systems Co., Ltd.
Measurement method: Irradiate with white light and observe interference at 530 nm

### (Light Transmittance Measurement)

Equipment: SolidSpec-3700DUV ultraviolet-visible-infrared spectrophotometer manufactured by Shimadzu Co., Ltd.
Slit width: 20 nm
Light source: halogen lamp

### Detector: PMT

Angle of incidence: 0 degrees

The results of the above measurements performed at each point (a, b, c) on the main surface of the substrate of example 1 and comparative example 1 are shown in Table 1. A light transmittance value was a minimum value in the wavelength range of 700 nm to 900 nm. A variation column in Table 1 shows the variation from an average value of each measurement.

TABLE 1

| | | | | | | | | Arithmetic mean | | | |
|---|---|---|---|---|---|---|---|---|---|---|---|
| | | Mn concentration | | Resistivity | | Vickers hardness | | height | | Light transmittance | |
| | | (cm−3) | Variation | (Ωcm) | Variation | (HV) | Variation | (nm) | Variation | (%) | Variation |
| Example 1 | a | 9.90E+18 | 17.48% | 6.79E+12 | 18.36% | 1345 | 1.46% | 0.42 | 18.87% | 5.97 | −18.29% |
| | b | 8.00E+18 | −5.06% | 5.50E+12 | −4.13% | 1320 | −0.43% | 0.34 | −3.77% | 7.78 | 6.48% |
| | c | 7.38E+18 | −12.42% | 4.92E+12 | −14.24% | 1312 | −1.03% | 0.30 | −15.09% | 8.17 | 11.82% |
| | Average | 8.43E+18 | | 5.74E+12 | | 1326 | | 0.35 | | 7.31 | |
| Comparative | a | 7.40E+18 | −0.89% | 4.68E+12 | −29.23% | 1314 | −1.65% | 0.32 | −38.85% | 8.08 | −34.31% |
| example 1 | b | 3.00E+18 | −59.82% | 3.56E+12 | −46.17% | 1308 | −2.10% | 0.23 | −56.05% | 24.70 | 100.81% |
| | c | 1.20E+19 | 60.71% | 1.16E+13 | 75.40% | 1386 | 3.74% | 1.02 | 94.90% | 4.12 | −66.50% |
| | Average | 7.47E+18 | | 6.61E+12 | | 1336 | | 0.52 | | 12.30 | |

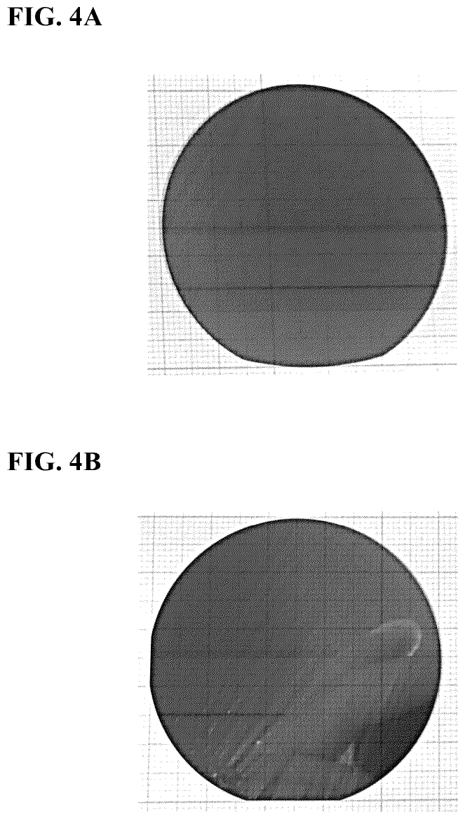

As shown in Table 1, in example 1, in which intermittent etching was performed and Mn doping was uniform, the variation in the Mn concentration was within ±20% from an average value, the variation in resistivity was within ±20% from an average value, the variation in a Vickers hardness was within ±2% from an average value, the variation in arithmetic mean height was within ±20% from an average value, and the variation in light transmittance was within ±20% from an average value. On the other hand, in comparative example 1, in which intermittent etching was not performed, the variation in each measurement value was larger than in example 1. Further, FIG. 4A shows a photograph of the substrate of example 1, and FIG. 4B shows a photograph of the substrate of comparative example 1. When the substrates of example 1 and comparative example 1 were visually inspected, the substrate of example 1 had no color unevenness as illustrated in FIG. 4A. On the other hand, in the substrate of comparative example 1, color unevenness was observed as illustrated in FIG. 4B.

As described above, it was confirmed that Mn doping could be uniform in the plane by performing intermittent etching during the growth of the growth layer. It was also confirmed that in the substrate in which Mn doping was uniform in the plane, the variations in resistivity, Vickers hardness, arithmetic mean height, and transmittance also fell within predetermined ranges.

### <Preferable Aspect of the Present Invention>

Preferable aspects of the present invention will be described below.

### (Supplementary Description 1)

A gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more; and

secondary ion mass spectrometry at a plurality of arbitrary points on the main surface reveals that a variation in the Mn concentration is within ±20% from an average value.

### (Supplementary Description 2)

A gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more, and

measurement at a plurality of arbitrary points on the main surface reveals that a variation in resistivity is within ±20% from an average value.

### (Supplementary Description 3)

A gallium nitride single crystal substrate according to supplementary description 1,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more, and

a variation in a Vickers hardness measured at a plurality of arbitrary points on the main surface is within ±2% from an average value.

### (Supplementary Description 4)

A gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more, and

a measurement of a surface roughness at a plurality of arbitrary points on the main surface reveals that a variation in arithmetic mean height Sa is within ±20% from an average value.

### (Supplementary Description 5)

A gallium nitride single crystal substrate,

which is a gallium nitride single crystal substrate having a diameter of 50 mm or more, with a low-index crystal plane closest to a main surface being (0001), and

in which a Mn concentration in the substrate is 5×10¹⁷ cm⁻³ or more, and

a variation in a minimum light transmittance in a wavelength range of 700 nm or more and 900 nm or less at a plurality of arbitrary points on the main surface is within ±20% from an average value.

Preferably, a variation in a maximum value of a light reflectance in a wavelength range of 600 nm or more and 700 nm or less at a plurality of arbitrary points on the main surface is within ±20% from an average value.

Further preferably, a variation in a minimum value of a light absorption coefficient in the wavelength range of 600 nm or more and 700 nm or less at a plurality of arbitrary points on the main surface is within ±20% from an average value.

### (Supplementary Description 6)

The gallium nitride single crystal substrate according to any one of the supplementary descriptions 1 to 5, wherein an average resistivity is 1×10⁸ Ωcm or more.

### (Supplementary Description 7)

The gallium nitride single crystal substrate according to any one of the supplementary descriptions 1 to 5, wherein a total content of Si and O is 1×10¹⁷ cm⁻³ or less.

### (Supplementary Description 8)

A method for producing a gallium nitride single crystal substrate, the method including the steps of:

(a) preparing a base substrate composed of a gallium nitride single crystal having (0001) that is a low-index crystal plane closest to a main surface;

(b) epitaxially growing a gallium nitride single crystal having a Mn concentration of 5×10¹⁷ cm⁻³ or more on the main surface of the base substrate; and

(c) obtaining a gallium nitride single crystal substrate having a diameter of 50 mm or more from the gallium nitride single crystal epitaxially grown in the step (b),

wherein in the step (b), a gas containing HCl is intermittently introduced to periodically etch a growth interface, thereby uniformly doping crystal with Mn.

1. A gallium nitride single crystal substrate,
which is a gallium nitride single crystal substrate having a diameter of 50 mm or more, with a low-index crystal plane closest to a main surface being (0001), and
in which a Mn concentration in the substrate is 5×10¹⁷ cm⁻³ or more; and
secondary ion mass spectrometry at a plurality of arbitrary points on the main surface reveals that a variation in the Mn concentration is within ±20% from an average value.

2. A gallium nitride single crystal substrate,
which is a gallium nitride single crystal substrate having a diameter of 50 mm or more, with a low-index crystal plane closest to a main surface being (0001), and
in which a Mn concentration in the substrate is 5×10¹⁷ cm⁻³ or more, and
measurement at a plurality of arbitrary points on the main surface reveals that a variation in resistivity is within ±20% from an average value.

3. A gallium nitride single crystal substrate according to supplementary description 1,
which is a gallium nitride single crystal substrate having a diameter of 50 mm or more, with a low-index crystal plane closest to a main surface being (0001), and
in which a Mn concentration in the substrate is 5×10¹⁷ cm⁻³ or more, and
a variation in a Vickers hardness measured at a plurality of arbitrary points on the main surface is within ±2% from an average value.

4. A gallium nitride single crystal substrate,
which is a gallium nitride single crystal substrate having a diameter of 50 mm or more, with a low-index crystal plane closest to a main surface being (0001), and
in which a Mn concentration in the substrate is 5×10¹⁷ cm⁻³ or more, and
a measurement of a surface roughness at a plurality of arbitrary points on the main surface reveals that a variation in arithmetic mean height Sa is within ±20% from an average value.

5. A gallium nitride single crystal substrate,
which is a gallium nitride single crystal substrate having a diameter of 50 mm or more, with a low-index crystal plane closest to a main surface being (0001), and
in which a Mn concentration in the substrate is 5×10¹⁷ cm⁻³ or more, and
a variation in a minimum light transmittance in a wavelength range of 700 nm or more and 900 nm or less at a plurality of arbitrary points on the main surface is within ±20% from an average value.

6. The gallium nitride single crystal substrate according to claim 1, wherein an average resistivity is 1×10⁸ Ωcm or more.

7. The gallium nitride single crystal substrate according to claim 1, wherein a total content of Si and O is 1×10¹⁷ cm⁻³ or less.

8. A method for producing a gallium nitride single crystal substrate, the method including the steps of:
(a) preparing a base substrate composed of a gallium nitride single crystal having (0001) that is a low-index crystal plane closest to a main surface;
(b) epitaxially growing a gallium nitride single crystal having a Mn concentration of 5×10¹⁷ cm⁻³ or more on the main surface of the base substrate; and
(c) obtaining a gallium nitride single crystal substrate having a diameter of 50 mm or more from the gallium nitride single crystal epitaxially grown in the step (b),
wherein in the step (b), a gas containing HCl is intermittently introduced to periodically etch a growth interface, thereby uniformly doping crystal with Mn.
